(19) United States
(12) Patent Application Publication
(10) Pub. No.: US 2023/0307890 A1
(43) Pub. Date: Sep. 28, 2023

(54) CASCADE LASERS

(71) Applicant: ETH Zürich, Zürich (CH)

(72) Inventors: Ruijun WANG, Guangzhou (CN); Jérôme FAIST, Zürich (CH)

(21) Appl. No.: 18/041,321

(22) PCT Filed: Aug. 18, 2021
(86) PCT No.: PCT/EP2021/072908

§ 371 Date: Feb. 10, 2023

(30) Foreign Application Priority Data
Aug. 21, 2020 (GB) 2013049.8

(51) Int. Cl. H01S 5/34; H01S 5/10

(52) U.S. Cl. CPC H01S 5/3402; H01S 5/1064; H01S 5/0655

(57) ABSTRACT

A quantum cascade laser or interband cascade laser for outputting a frequency comb. The laser's active waveguide comprises a combination of narrow and wide sections which are engineered in combination such that the laser is operable to produce lasing only in the fundamental mode across the operating wavelength range, the narrow section squeezing light propagating in the waveguide to output a frequency comb via four-wave mixing. The narrow and wide sections are further engineered to reduce the waveguide's net GVD, and also to reduce the GVD variation across the operating range compared to a comparable waveguide that is of constant width, thus producing a more stable frequency comb. The proportion of the laser's full dynamic range (i.e. from threshold to the rollover current where the maximum output power is achieved) over which lasing remains in the frequency comb regime is thereby increased compared with a constant width single mode waveguide.

### BACKGROUND OF THE INVENTION

The invention relates to cascade lasers, more particularly to quantum cascade lasers (QCLs) and interband cascade lasers (ICLs).

QCLs and ICLs are semiconductor lasers based on a multi-quantum well structure, in which respectively the inter-subband and inter-band transitions in the quantum wells are used as the lasing transitions. They have been realized as edge-emitting semiconductor lasers, which can emit across a wide part of the infrared spectral range (3-20 μm) and operate in continuous-wave (CW) mode at room temperature. QCLs that emit in the mid-infrared region do not operate successfully with passive mode locking because of the very short upper state lifetime of inter-subband transitions in the quantum wells. Instead, the large third-order nonlinearity of the active regions is exploited, since it introduces a four-wave-mixing process in the device, which leads to phase-locking of the Fabry-Perot modes, thereby generating frequency combs. A frequency comb consists of a discrete number of coherent lines equally spaced in frequency. In recent years, frequency comb generation from QCLs and ICLs has been demonstrated based on a simple Fabry-Pérot cavity configuration. Typically, a QCL or ICL lases in three operational regimes which are progressed through as the drive current is increased. The three regimes are the single-mode regime, the frequency comb regime and the high phase noise regime. QCLs or ICLs are used as comb generators in dual-comb spectrometers (DCS) for which a matched pair of QCLs or ICLs is used with one of the pair being driven to output a frequency comb with a frequency spacing that is slightly different from the other. For DCS, and other cascade laser applications, stability of the frequency comb is important.

In QCLs based on a conventional waveguide design, the laser is prone to hop unpredictably between the frequency comb regime and the high-phase noise regime, which is detrimental to stability and performance. Several approaches have been adopted to achieve more stable frequency comb operation and to increase the portion of the lasing range over which the laser operates in the frequency comb regime. When using four-wave-mixing to generate frequency combs from a QCL, it is known that the group velocity dispersion (GVD) of the waveguide is important for frequency comb stability. The principal components of GVD in QCLs are the material dispersion, the gain dispersion and the modal dispersion of the waveguide formed in the active region of the laser. Both the material dispersion and the gain dispersion are determined by the choice of materials system of the QCL and also on the QCL driven condition since the gain dispersion is dependent on the drive current.

The following approaches are known for changing the GVD away from its natural, materials-based values in order that the QCL has GVD values better suited to generating stable frequency combs.

WO2019110650A1 (IRsweep AG) and the corresponding journal publication J. Hillbrand et al., Optics Letters 43(8), 1746-1749 (2018) disclose adding a planar mirror placed behind the back facet of the QCL so that the back facet and an external planar mirror form a Gires-Tournois etalon. This allows the GVD to be tuned by tuning the distance between the QCL chip's back facet and the external planar mirror and thereby improve comb stability.

R. Wang, F. Kapsalidis, M. Shahmohammadi, M. Beck, and J. Faist, “Ridge-width dependence of the dispersion and performance of mid-infrared quantum cascade laser frequency combs,” in Conference on Lasers and Electro-Optics, OSA Technical Digest (Optical Society of America, 2020), paper STh1E.1 publishes studies of the effect of ridge width on the dispersion and frequency comb performance of QCLs. It was found that GVD increases with decreasing waveguide width. Moreover, narrower waveguides provide broader lasing spectra but also have weaker comb stability, which could however be compensated for by integrating the QCL in a Gires-Tournois (GTI) interferometer.

WO2019068554A1 (ETH Zürich) and the corresponding journal publication Y. Bidaux et al., Laser & Photonics Reviews 12, 1700323 (2018) use waveguide engineering to correct the GVD. A second, passive waveguide is arranged alongside the first, active waveguide of the QCL. The optical coupling between the two waveguides through the evanescent tails of the individual modes significantly reduces the net GVD which in turn improves stability of the frequency comb.

### SUMMARY OF THE INVENTION

According to a first aspect of the disclosure there is provided a cascade laser having an operating wavelength range over which it is operable to output a frequency comb, the laser comprising end mirrors that form a resonant cavity and a waveguide arranged between the end mirrors, the waveguide comprising: a narrow part that supports at least a fundamental mode across the operating wavelength range and squeezes light propagating in the waveguide to output a frequency comb via four-wave mixing; and a wide part having a width greater than the narrow part, wherein the narrow and wide parts are configured in combination such that the laser is operable to produce lasing only in the fundamental mode across the operating wavelength range for frequency comb generation.

With this design, the waveguide can be realised with a group velocity dispersion across the operating wavelength range that is below one of: 700, 600, 500, 400, 300, 200 and 100 fs²/mm.

With this design, the waveguide can be realised with a total variation in group velocity dispersion across the operating wavelength range that is below one of: 300, 250, 200, 150, 100 and 50 fs²/mm.

This design also allows the proportion of the cascade laser's full dynamic range (i.e. from threshold to the rollover current where the maximum output power is achieved) over which the laser output remains in the frequency comb regime to be increased compared with a cascade laser based on a constant width single mode waveguide. For example, the operating wavelength range for frequency comb generation can be at least one of 20%, 25% and 30% of the full dynamic range.

Certain embodiments can be realised with the narrow part having a positive or negative GVD across the operating wavelength range, and the wide part having a negative or positive GVD across the operating wavelength range of opposite sign to the GVD of the narrow part, so that the respective GVDs of the narrow and wide parts counteract each other. For example, the narrow part may have a positive GVD across the operating wavelength range, and the wide part may have a negative GVD across the operating wavelength range. The positive GVD of the narrow part is then partially or wholly offset by the negative GVD of the wide part to provide a waveguide with a reduced magnitude of the GVD. In particular, it is possible to engineer a low, net negative GVD, which is advantageous, since low and net negative GVD can favour stable comb generation over a broader range of drive current compared with a waveguide with a large GVD or a positive GVD. The proportion of the laser's full dynamic range (i.e. from threshold to the rollover current where the maximum output power is achieved) over which it remains in the frequency comb regime is increased compared with a constant width single mode waveguide. In other examples, the counteracting GVD contributions of the narrow and wide parts may be engineered to produce a net GVD that is as close to zero as possible, or even a net positive GVD if desired. In certain embodiments, the absolute value of the magnitude of the GVD across the operating wavelength range may be kept below one of: 700, 600, 500, 400, 300, 200 and 100 fs²/mm.

Certain embodiments can be realised with the GVD of the narrow part having a negative or positive slope as a function of wavelength, and the GVD of the wide part having a positive or negative slope as a function of wavelength that is of opposite sign to that of the narrow part, so that the narrow and wide parts in combination result in the waveguide having a reduced variation in GVD across the operating wavelength range compared with either the narrow or wide parts alone. A negative slope GVD is one with a GVD that decreases as wavelength increases. A positive slope GVD is one with a GVD that increases as wavelength increases.

With this approach it is possible to flatten the waveguide's GVD variation which is beneficial for providing a laser that emits in the frequency comb regime over a broader range of drive current and with good stability. The proportion of the cascade laser's full dynamic range (i.e. from threshold to the rollover current where the maximum output power is achieved) over which the laser output remains in the frequency comb regime is therefore increased compared with a cascade laser based on a constant width single mode waveguide. In certain embodiments, the flattening of the GVD distribution is such that the total variation in GVD across the operating range is kept below one of: 300, 250, 200, 150, 100 or 50 fs²/mm.

The presence of the narrow part, which may for example be so narrow that only the fundamental mode is supported, inhibits lasing of higher-order modes supported in the wide part, thereby allowing the waveguide to incorporate these wider sections while still only lasing in one fundamental mode. For example, in the long mid-infrared wavelength range, the material dispersion of InP and related Group Ill-V materials is negative, so that wide waveguides in these materials where the GVD is dominated by the material dispersion will have negative GVD as is beneficial for stable comb generation. However, with a conventional QCL design with a constant width, narrow single-mode waveguide the waveguide has a positive GVD owing to the dominant contribution to GVD from the modal dispersion. Widening the constant width waveguide to reduce the modal dispersion contribution is however not feasible, since it would result in the waveguide supporting higher order modes which would then also attain the gain threshold and lase together with the fundamental mode. Multiple lasing modes would be detrimental for the comb stability and exclude spectroscopic applications. In our proposed design, we can tolerate the presence of the wide part, even if it supports higher order modes, since the higher order modes are suppressed from lasing through the presence of the narrow part. This in turn enables the GVD of the waveguide to be engineered more freely, e.g. to provide a small net negative GVD and/or a GVD that varies by a relatively small amount over the operating wavelength range.

In some embodiments, the wide part has a length that is greater than the length of the narrow part. The wide part can have a length that is greater than half the optical path length between the end mirrors. For a non-folded cavity and when the end mirrors are formed on the chip's end facets, the optical path length will correspond to the chip length. In some embodiments, the length of the wide part is at least one of 50%, 60% or 70% of the sum of the lengths of the wide and narrow parts. The wide part can thus have a length that is greater than at least one of 50%, 60% and 70% of the length of the narrow part or the optical path length between the end mirrors.

Various alternative waveguide structures can achieve the proposed combination of wide and narrow parts. A few possibilities are as follows:
the wide part comprises a length portion of a constant width and the narrow part consists of the narrow end of one or two tapered portions that each join to the wide part and then taper down in width from the constant width of the wide part.
the narrow part consists of one or more tapered portions of varying width.
the wide part consists of one or more tapered portions of varying width.
the narrow part and the wide part consist of one or more tapered portions of varying width.
the narrow part comprises a section of a first constant width and the wide part comprises a section of a second constant width greater than the first constant width, and wherein the waveguide further comprises a tapered portion of varying width to provide a continuous transition between the first and second constant width portions.

Having a tapered section to dovetail between a wide section and a narrow section is advantageous, since it reduces radiation losses between the sections. In particular, if the taper is sufficiently gradual, the conversion of high-order modes in the wide section to the fundamental mode in the narrow section is accomplished in a way that radiation losses are kept as low as possible.

In certain embodiments, the waveguide is formed in a semiconductor chip comprising a plurality of layers. The layers provide the necessary refractive index profile for waveguide confinement in the direction perpendicular to the plane of the layers, i.e. the growth direction, referred to as vertical confinement. The layers include a waveguide core layer, which itself comprises a sequence of layers to provide multiple quantum wells (MQWs) with respective subbands that define transition energies for cascade laser action, and lower and upper waveguide cladding layers arranged either side of the waveguide core layer to provide vertical confinement of waveguiding modes. For QCL embodiments, the MQW subbands define at least one intersubband transition operable to generate quantum cascade laser action. For ICL embodiments, the MQW subbands define at least one interband transition operable to generate interband cascade laser action. The semiconductor chip further comprises lateral structure to provide lateral confinement of the waveguiding modes, i.e. confinement in one dimension perpendicular to the growth direction. The layer structure and the lateral structures thus collectively define the waveguide. The semiconductor chip further comprises front and back facets and these may be used to provide the end mirrors (rather than using external mirrors which is another option). The cavity length may be the distance between the front and back facets in an edge-emitting semiconductor laser implementation.

Example semiconductor materials systems for fabricating cascade lasers according to the disclosure include: GaInAs/AlInAs, which may be lattice-matched to InP and so use an InP substrate; GaAs/AlGaAs and InGaAs/AlAsSb. The lateral confinement to create the waveguide may use any known structure, for example a ridge waveguide where the semiconductor is etched through the active region to create parallel trenches and create an isolated stripe or a buried heterostructure where the ridge waveguide is encapsulated by a regrown laterally semi-insulating semiconductor material.

### BRIEF DESCRIPTION OF THE DRAWINGS

This invention will now be further described, by way of example only, with reference to the accompanying drawings.

FIG. 1A is a schematic perspective view of a ridge waveguide QCL according to a first embodiment of the disclosure with a multi-section waveguide structure.

FIG. 1B is a schematic plan view of the multi-section waveguide of FIG. 1A.

FIG. 1C is a schematic cross-section of the ridge waveguide QCL of FIGS. 1A & 1B, the cross-section being perpendicular to the optical axis ‘O’ of the waveguide as shown in FIG. 1B.

FIG. 2 is a graph plotting group velocity dispersion (GVD in fs²/mm) against wavelength in wavenumbers (v in cm⁻¹) showing simulation results for a narrow (4 μm) and a wide (12 μm) waveguide as well as a weighted average (AV) for the two waveguides combined.

FIG. 3 is a schematic perspective view of a comparative conventional design to be compared with FIG. 1A.

FIG. 4 is a graph plotting group velocity dispersion (GVD in fs²/mm) against wavelength in wavenumbers (v in cm⁻¹) showing experimental results for an inventive example QCL fabricated according to the first embodiment (solid line) and an otherwise equivalent comparative example (dashed line) fabricated according to FIG. 3.

FIG. 5 shows performance of the same inventive example QCL as for FIG. 4 in terms of measured voltage (V in volts) and output power (P in mW) as a function of drive current (I in amps) at operating temperatures of −10° C., +10° C. and 30° C.

FIG. 6 is a graph plotting output power (P in dBm) against frequency (F in GHz) showing the measured beatnote spectra for the same inventive example QCL of FIGS. 4 & 5 at an operating temperature of +10° C.

FIG. 7 shows a beam image measured in far field for the inventive example at an operating temperature of −10° C.

FIGS. 8A to 8D, which are comparable with FIG. 1B, show various alternative embodiments.

### DETAILED DESCRIPTION

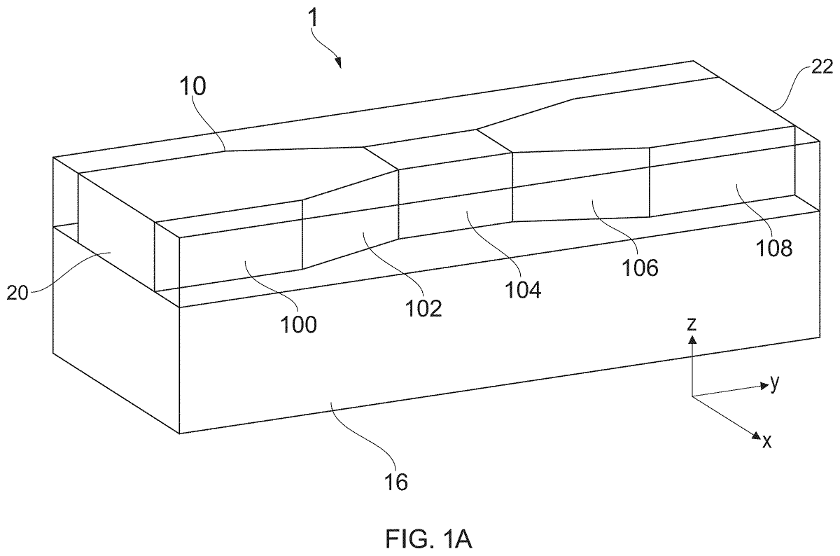

FIGS. 1A and 1B are schematic perspective and plan views of a QCL 1 according to a first embodiment comprising a waveguide 10 having a principal optical axis ‘O’ arranged on a substrate 16. The waveguide 10 extends in the y-direction. FIG. 1C is a schematic cross-section of the QCL 1 showing its ridge waveguide structure which is based on a sequence of epitaxially deposited semiconductor layers. The growth direction of the epitaxial semiconductor layers that form the QCL structure is the z-direction. The cross-section of FIG. 1C is perpendicular to the optical axis ‘O’ of the waveguide 10. The waveguide 10 has five sections 100, 102, 104, 106 and 108. There is a narrow waveguide section 104 at the center and two wide waveguide sections 100 and 108 at each end. In addition, there are two tapered sections 102 and 106 which interconnect the wide sections 100 and 108 with the narrow section 104.

The waveguide 10 has a length L₁₀ being bounded by front and back end facets 20 and 22 which form the laser resonator cavity, i.e. a Fabry-Perot cavity. The other widths and lengths are illustrated with W and L and the appropriate reference numeral in subscript. The two wide sections 100 and 108 may have lengths and widths (and heights) that are different from each other or the same. The widths W₁₀₀ and W₁₀₈ are selected to support fundamental and high-order modes in the respective sections 100 and 108 while the width W₁₀₄ is selected to only support the fundamental mode in the section 104. In the sections 102 and 106, the respective widths W₁₀₂ and W₁₀₆ are linearly varied along the y-direction to provide a smooth transition between section 100 and section 104, as well as section 104 and section 108 respectively. In these tapered sections, the waveguide is gradually tapered so that the conversion of high-order modes to the fundamental mode is gradually accomplished in a way that radiation losses are kept as low as possible. For example, the length of each of the tapered sections L₁₀₂ and L₁₀₆ may be at least 200 μm in the example case of a QCL with emission wavelengths around 8 μm. The wide waveguide sections 100 and 108 are dimensioned to support multiple waveguiding modes, i.e. are multimode. (It is noted that a tapered section may be considered as being subdivided into a multi-mode portion and a single mode portion, with there being a threshold width along the taper where the tapered section switches over from supporting multiple modes to only supporting the fundamental mode.) The narrow waveguide section 104 is dimensioned to be single mode. The wide multimode waveguide sections 100, 108 have a negative GVD, while the narrow single mode waveguide section 104 has a positive GVD. The different signs of the GVDs of the wide and narrow sections result in their GVD contributions partially counteracting each other to provide a net negative GVD for the waveguide as a whole with a reduced magnitude compared with the negative GVD wide sections. The different slopes of the GVDs of the wide and narrow sections result in an overall reduced slope to provide the waveguide as a whole with a flatter GVD (i.e. less GVD variation across a specific frequency range of interest where the QCL is operating in the frequency comb regime) compared to the GVD variation in the wide sections 100, 108. The waveguide 10 is thus engineered to provide a relatively flat and relatively small, net negative GVD for the Fabry-Perot cavity. In addition, when considering laser action with round trip gain, it will be appreciated that the single mode waveguide section effectively filters out higher-order modes that are supported in the multimode sections, so that these higher-order modes do not attain the lasing threshold.

In addition to the above-described advantages of allowing the GVD to be engineered, the construction has other advantages as follows.

Having a significant part of the length of the waveguide 10 formed by wider multimode sections 100, 108 is advantageous, since the optical overlap of the fundamental mode with waveguide sidewall is much reduced. Therefore, the undesired optical feedback from residual surface roughness in the wider waveguide sections 100, 108 is reduced which improves comb stability.

Having a narrow waveguide part can also serve to squeeze the light propagating in the waveguide, thereby enhancing the optical nonlinearity and improving the generation of frequency comb via four-wave mixing.

Having the front facet 20 (and the rear facet 22 if output is from both end facets) formed on a wider waveguide section can improve the output optical power of the QCLs, which may help prolong device lifetime and reduce the chance of burnout. It can also reduce the divergence angle (solid angle) of the output beam(s).

FIG. 1B shows the waveguide 10 to be straight and formed of straight sections. Moreover, FIG. 1B shows that the waveguide sidewalls are planar. However, in variants the waveguide and its sections could be curved and/or have non-planar sidewalls. Moreover, in the illustrated embodiment, the waveguide sections 100, 104 and 108 have constant widths. However, in variants these widths could vary along the respective section. FIG. 1C shows the waveguide 10 as having a constant height (z-dimension), which is convenient for fabrication. However, if desired, the different sections could have different heights, or heights that vary within each section.

FIG. 1C shows layers of a ridge waveguide with buried heterostructure for realising the QCL 1 of the first embodiment. The multiple section waveguide 10 is grown on a substrate 16. From the substrate upwards in the growth direction the epitaxial layers are: a lower cladding layer 120, a lower waveguide cladding layer 122, a waveguide core layer 124 which provides an optical gain when the device is electrically pumped, an upper waveguide cladding layer 126 and an upper cladding layer 128. The cladding layers 120 and 128 have a lower refractive index than the waveguide core layer 124 to provide for the vertical confinement of the optical mode(s). Through suitable lithographic processes, a ridge waveguide structure is formed by etching or otherwise removing material from two sides of the layer stack. The optical modes are thus laterally confined by the formation of the ridge. On either side of the ridge, insulating material is formed, e.g. by deposition, which is shown as insulating layers 12a and 12b. The insulating material provides electrical insulation and better heat conduction away from the waveguide 10 when the device is lasing. A top electrode 14 is formed as a layer on the top of the stack. A bottom electrode 18 is formed on the underside of the substrate 16. The electrodes 14, 18 may be made of a suitable metal or metallic materials, e.g. may consist of multiple layers of metals, the one at the surface typically being Au.

The narrow and wide waveguide sections thus share a common layer structure to provide common vertical confinement and are distinguished by variation of lateral confinement through the ridge.

The above-described example layer structure for the QCL is not specific to the present disclosure and the skilled person will understand that any known layer structures for QCLs could be used. Moreover, the mode confinement may be realized in other structures, such as a ridge waveguide structure encapsulated with dielectric layer (e.g., silicon nitride). Any semiconductor materials system suitable for QCLs may be used, e.g. in the GaAlInAsP materials system, the GaAlInAs materials system or the InGaAlAsSb materials system.

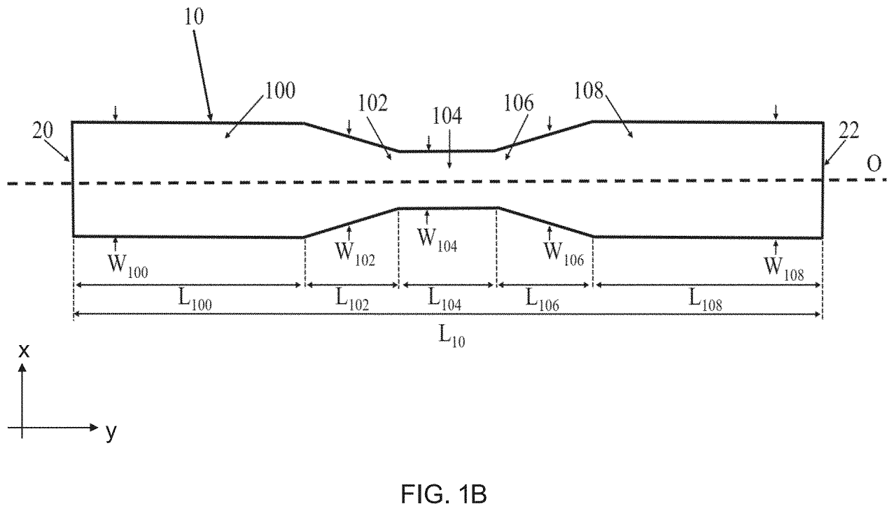

FIG. 2 is a graph plotting group velocity dispersion (GVD in fs²/mm) against wavelength in wavenumbers (v in cm⁻¹) showing simulation results for a narrow waveguide (W=4 μm) and a wide waveguide (W=12 μm) as well as a weighted average (AV) for the two waveguides. The graph plots three curves. The top curve is the calculated GVD for the 4 μm-wide constant width waveguide. The bottom curve is the calculated GVD for the 12 μm-wide constant width waveguide. The middle curve is the weighted average (AV) of the upper and lower curves. The weighted average simulates the structure of the first embodiment with two 12 μm-wide multimode sections, with a combined length of 2.5 mm (e.g. equal lengths such that L₁₀₀=L₁₀₃=1.25 mm) and an interconnecting 4 μm-wide single mode section, with a length L₁₀₄=0.5 mm. When the waveguide width is 4 μm, the GVD value is positive with values of approximately 1000±100 fs²/mm across an intended operating wavelength range for comb generation of approximately 1210 to 1275 cm⁻¹ (see faint dotted lines). On the other hand, with a waveguide width of 12 μm, there is a negative and relatively flat GVD. This difference is because different dispersion mechanisms dominate the GVD for these two waveguide widths.

The three main components of GVD are: the material dispersion, the gain dispersion and the modal dispersion of the waveguide. For a wide waveguide, the modal confinement is tight and the wavelength dependence of the modal confinement is weak, leading to the GVD being dominated by the material dispersion, which is negative for the chosen materials. For a narrow waveguide, the modal confinement is strongly wavelength-dependent resulting in the GVD being dominated by modal dispersion, which is positive and strongly varying with wavelength. Even though the GVD of the 12 μm-wide waveguide is quite flat compared to the 4 μm-wide waveguide, the weighted average curve shows that a still flatter GVD is possible by combining wide and narrow waveguide sections in a single waveguide as proposed. In particular, the opposite slopes in the GVD profiles of the narrow and wide waveguide sections can be used to create a flatter GVD over a wider wavelength range (in the example curve in the range of about 1250 to 1500 cm⁻¹). Moreover, the GVD curves of the wide and narrow sections can be combined so that the net GVD is negative but less strongly negative than for the wide sections alone. The simulation predicts a flat and net negative GVD over a wide range of useful operation wavelengths for a QCL by suitable choice of materials and the ratio of lengths of the wide and narrow waveguide sections.

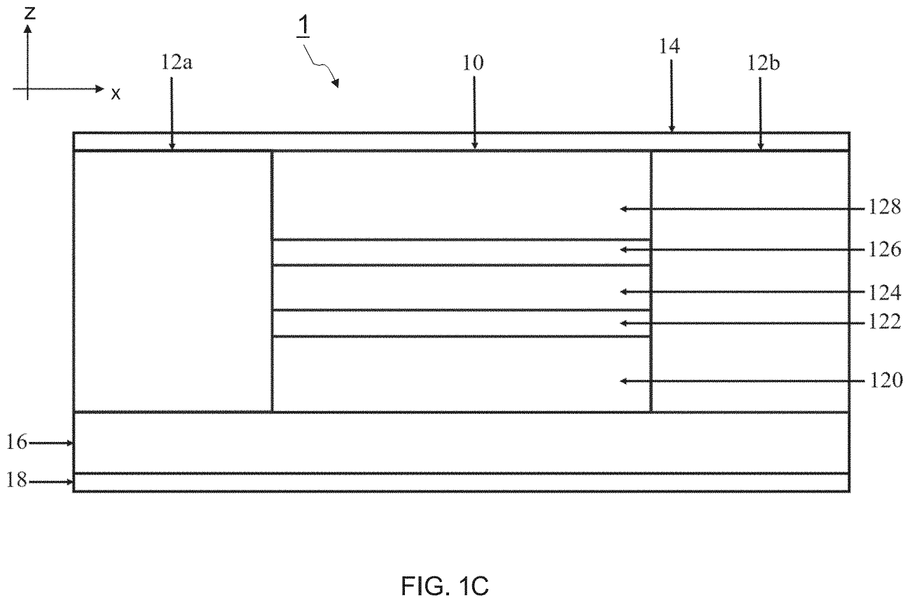

FIG. 3 is a schematic perspective view of a comparative conventional design of QCL 1 with a uniform width single mode waveguide 10 arranged on a substrate 16 and extending between the front and back facets 20, 22. This illustration of the comparative design is to be compared with that of FIG. 1A.

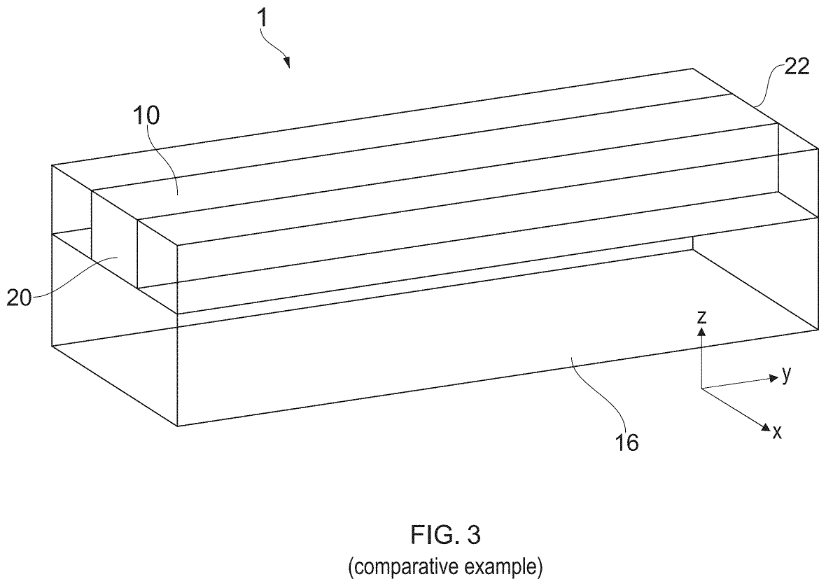

To allow a direct performance comparison between the invention and the prior art, we fabricated two QCLs, one according to the first embodiment as shown in FIGS. 1A to 1C (inventive example) and another with a conventional design as shown in FIG. 3 (comparitive example). The comparitive example and the inventive example were fabricated identically apart from the width progression and width values of their respective waveguides as produced by post-epitaxy lithography. They were fabricated from the same wafer and also had the same cavity lengths. The experimental results are described with reference to FIGS. 4 to 6. The QCL has laser emission wavelengths around 8 μm.

The layers in the inventive and comparative examples were the same as follows:
lower and upper cladding layers 120, 128: InP
lower and upper waveguide cladding layer 122, 126: InGaAs
waveguide core layer 124: MQW of InGaAs/AlInAs
insulation layers 12a, 12b: InP: Fe.
top electrode 14: Ti/Pt/Au with Au to the surface
bottom electrode 18: Ge/Au/Ni/Au with Au to the surface

Layer thicknesses were also the same as follows:

TABLE 1

| Layer | Material | Thickness, T |
|---|---|---|
| 120 | InP | 2 μm |
| 122 | InGaAs | 0.4 μm |
| 124 | InGaAs/AlInAs | 2.0 μm |
| 126 | InGaAs | 0.4 μm |
| 128 | InP | 3.5 μm |

The dimensions of the waveguide of the inventive example were as follows.

TABLE 2

| | | |
|---|---|---|
| Section | Length, L | Width, W |

| | | | |
|---|---|---|---|
| 100 | 1000 | μm | 12 μm |
| 102 | 500 | μm | tapered 4 to 12 μm |
| 104 | 500 | μm | 4 μm |
| 106 | 500 | μm | tapered 4 to 12 μm |
| 108 | 1500 | μm | 12 μm |
| Combined Length | 4 | mm | n/a |

The (constant) waveguide width of the comparative example is 7 μm, which is narrow enough to make the waveguide single mode. All other dimensions were the same as for the inventive example.

FIG. 4 is a graph showing experimental results for the inventive example and the comparative example. The graph plots GVD in units of fs²/mm against wavelength in units of wavenumber, v in cm⁻¹. The GVD data were acquired by analysing the interferogram of the emission light when the devices were driven with a drive current of 40 mA below threshold. With faint dotted lines, the graph also shows the operating wavelength range that corresponds to the dynamic range of the drive current (referred to as the dynamic current range) in which the laser outputs stably in the frequency comb regime. We see the operating wavelength range of the inventive example (also shown in FIG. 2) is between about 1210 and 1275 cm⁻¹ (see faint lines) which corresponds to drive currents in the range of about 1100 to 1400 mA. The dynamic range of the drive current is thus about 300 mA. This compares with a dynamic range for frequency comb generation with our comparative example, which is about 100 mA, and moreover not stable within that range, since the laser is prone to jump unpredictably to the high phase noise regime. The dynamic current range of the inventive example is thus about three times greater than that of the comparative example, thereby giving a correspondingly broader range of emission wavelengths, and the frequency comb regime is more stable. Over the indicated operating wavelength range, the inventive example has GVD values varying by approximately 100 fs²/mm between −400 and −500 fs²/mm, whereas the comparative example has GVD values that vary by approximately 300 fs²/mm from about −450 fs²/mm at 1210 cm⁻¹ to −750 fs²/mm at 1275 cm⁻¹. Moreover, the comparative example has a GVD value that drops quite rapidly at the long wavelength end of the illustrated range. This kind of relatively steeply falling GVD is not conducive to generation of a stable frequency comb. As explained above, the flatter GVD curve of the inventive example can be attributed to the positive GVD (negative slope) of the narrow waveguide section partially offsetting the negative GVD (positive slope) of the wide waveguide sections.

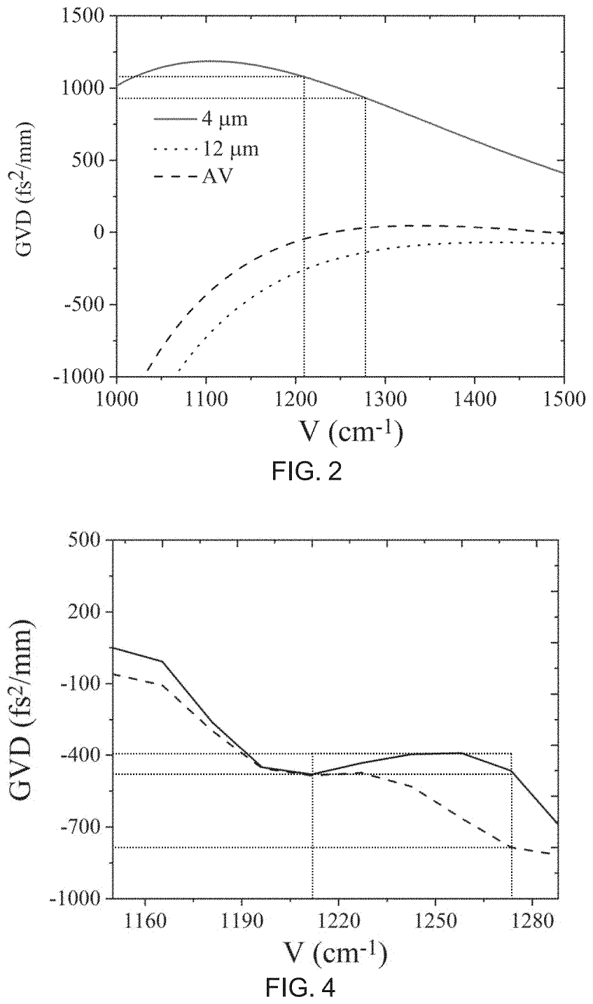

FIG. 5 shows performance of the inventive example in terms of measured voltage, V, and output power, P, as function of drive current, I. The measured output power is taken from the output from the front facet only, i.e. we did not additionally measure the output from the back facet. The total output power from both end facets should therefore be approximately double what is shown in the graph given that the inventive example had respective reflectivities of its front and back facets that were equal and the cavity was otherwise symmetrically designed in respect of the front and back. The inventive example is operated in CW mode and the different curves are for different operating temperatures as controlled by a Peltier cooler. The operating temperatures, or more precisely the temperature of the cooled heat sink on which the laser chip is mounted, range from −10° C. to +30° C. The maximum output power is approximately 385 mW at −10° C. which reduces to 155 mW at +30° C. The threshold current of the laser at −10° C. is 680 mA, which correspond a current density of 1.7 kA/cm², and the threshold current increases to 933 mA (2.33 kA/cm²) at +30° C. It can be seen that, if any given power-current curve is followed from threshold, each arrives at a small plateau feature (kink). For the −10° C. curve, for example, the plateau can be seen at a drive current of about 1.0 A. These plateaus indicate the transition from the laser operating in the single-mode regime to the frequency comb regime.

Although not shown in FIG. 5, we note that the inventive example can also be driven in pulsed operation as an alternative to CW operation. In pulsed operation, we measured performance with a pulse duration 104 ns and a pulse period of 10.4 μs. The laser emitted up to 1.16 W with a threshold current density of 1.25 kA/cm² at an operating temperature of −15° C., the output power reducing to 0.93 W with a threshold current density of 1.55 kA/cm² at the higher operating temperature of +20° C.

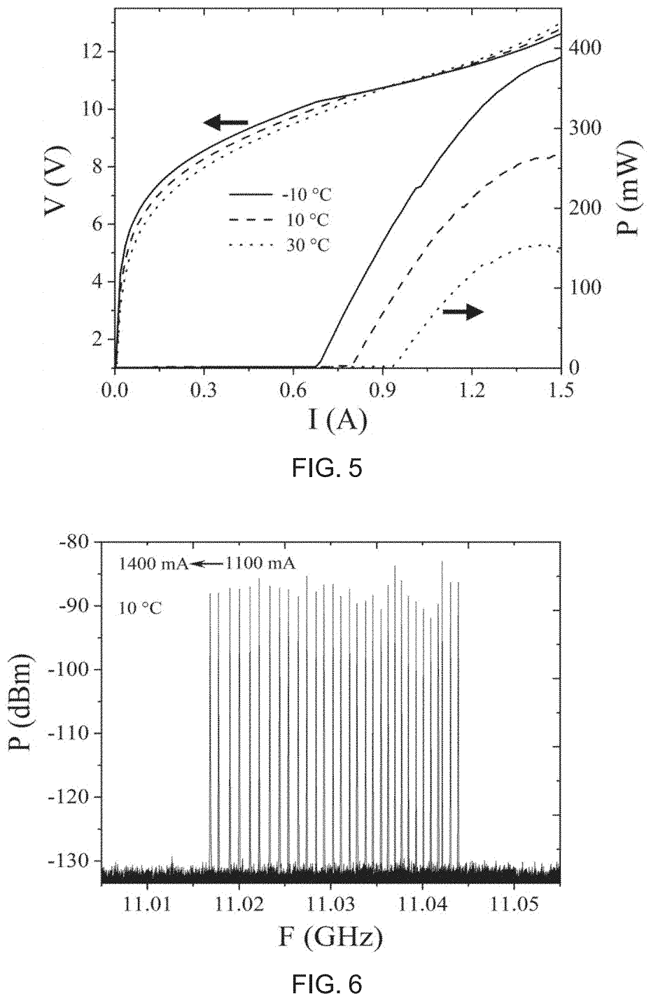

FIG. 6 shows a representative example of a measured beatnote spectra for the inventive example taken when operating at a heat-sink temperature of +10° C. The beatnote signal is the result of intermode beating between different lasing modes of the QCL. The spectra were acquired using a spectrum analyser with a span range of 100 MHz and resolution bandwidth (RBW) of 100 Hz. With the inventive example, sharp and strong beatnotes, each having a full width half maximum (FWHM) of less than 1 kHz, were observed in a drive current range of 1100-1400 mA. In contrast, for the comparative example, similarly narrow beatnotes were only observed over a much narrower drive current range of about 100 mA. This comparison indicates that better quality, i.e. more stable, frequency combs can be obtained using our proposed design compared to a conventional design.

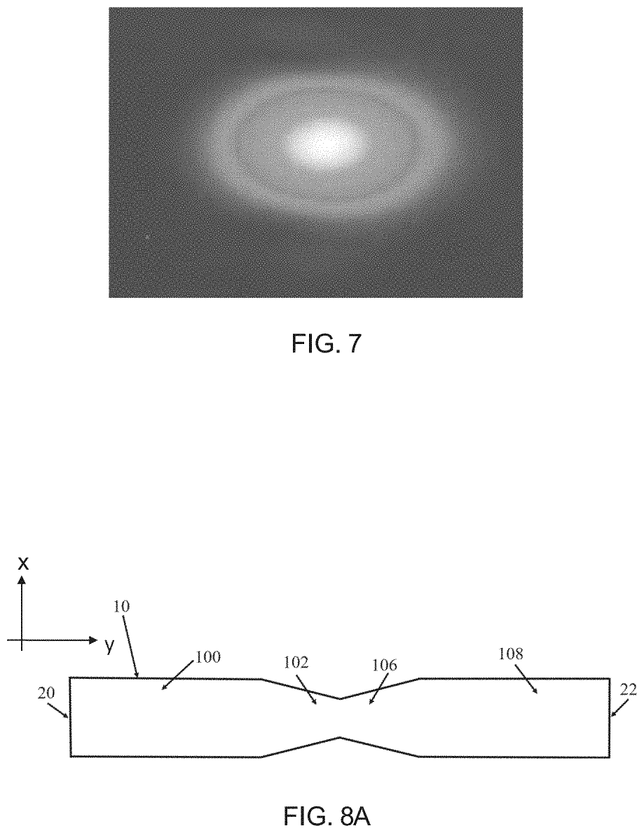

FIG. 7 shows a beam image measured in far field for the inventive example. The operating temperature of the laser was −10° C. and the current was set to 1.25 A. The beam image clearly shows that only one fundamental mode is lasing, not any higher-order modes of either the narrow or wide sections. The illustrated beam image, which is representative of the inventive example's behaviour under a variety of operating conditions, shows that our design produces a laser that suppresses lasing of the higher-order transverse modes in the wider sections as intended.

In summary, we have described an inventive example QCL for outputting a frequency comb. The laser's active waveguide comprises one narrow section and two wide sections. The narrow section is engineered through its narrow width to have a positive GVD with a negative slope as a function of wavelength, whereas the wide sections are engineered through their wider width to have a positive GVD with a negative slope as a function of wavelength. The different signs and slopes of the GVD components combine to give the waveguide a net negative GVD with a smaller variation as a function of wavelength than a comparable waveguide that is of constant width, thus producing a more stable frequency comb.

Various alternative waveguide structures can achieve the proposed combination of narrow and wide sections. In the main embodiment described above, there are five waveguide sections. However, QCL waveguide structures according to our design principles can be realized with more or fewer sections and with different section orders. Some embodiments may have two or more narrow sections, for example, which may be interconnected via one or more wide sections. Moreover, there may be additional waveguide sections which are not active, i.e. do not contribute to gain, such as absorber or filter sections or functionally inactive sections where carriers are not injected.

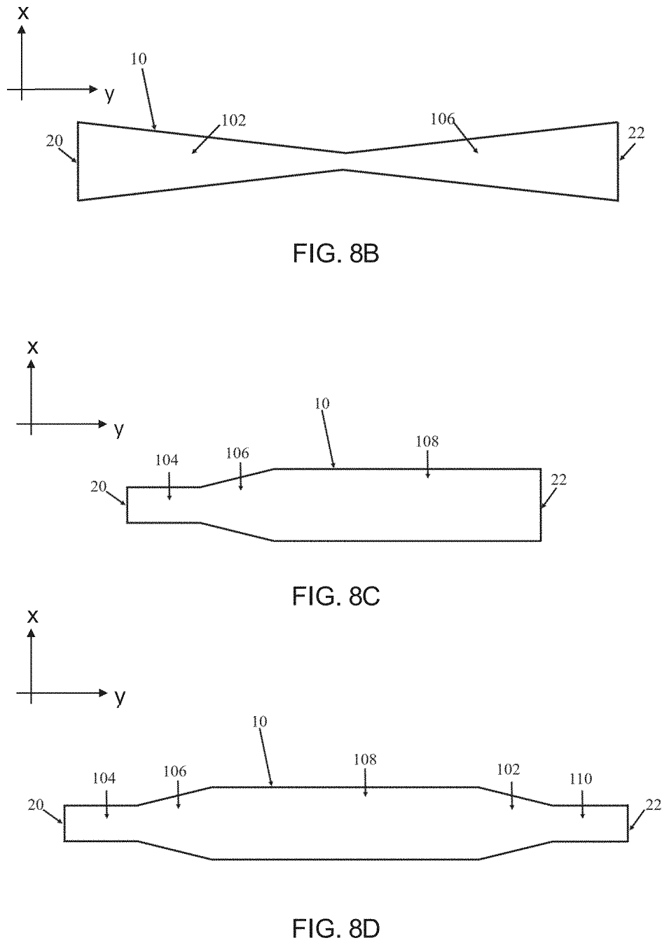

FIGS. 8A to 8D, which are comparable with FIG. 1B, show some alternatives by way of example.

FIG. 8A shows an example embodiment in which, by way of comparison to FIG. 1B, the constant width single-mode section 104 is omitted and the single-mode feature is achieved through the two tapered sections 102 and 106 whose wide ends adjoin the wide sections 100 and 108. The role of single-mode waveguide in dispersion compensation and nonlinearity enhancement is fulfilled by the narrower parts of the tapered waveguide sections 102 and 106 where they meet each other. In this waveguide, the high-order modes are filtered by the narrower parts of the two tapered waveguide sections.

FIG. 8B shows an example embodiment in which, by way of comparison to FIG. 1B, the constant width wide and single-mode sections 100, 104 and 108 are all omitted and the waveguide has a butterfly-like profile from two tapered sections 102 and 106. The wider parts of the tapered sections support multiple modes, whereas the narrow parts of the tapered sections, in the vicinity of their junction, support only the fundamental mode.

FIG. 8C shows an example embodiment in which, by way of comparison to FIG. 1B, the tapered section 102 and wider section 100 on the side of the front reflector 20 are both omitted. There is thus only one wider section 108, rather than two as in the previous embodiments, and only one tapered section 106.

FIG. 8D shows an example embodiment in which there are two narrow sections 104 and 110 at either end of the cavity adjacent mirrors 20 and 22 respectively and a central wide section 108. The wide section 108 is connected to the two narrow sections 104 and 110 by respective tapered sections 106 and 104 respectively. This design may help to reduce feedback and stray light effects.

It will be clear to one skilled in the art that many improvements and modifications can be made to the foregoing exemplary embodiment without departing from the scope of the present disclosure.

1. A cascade laser having an operating wavelength range over which it is operable to output a frequency comb, the laser comprising end mirrors that form a resonant cavity and a waveguide arranged between the end mirrors, the waveguide comprising:
a narrow part that supports at least a fundamental mode across the operating wavelength range and enhances optical non-linearity to improve generation of a frequency comb via four-wave mixing; and
a wide part having a width greater than the narrow part, wherein the narrow and wide parts are configured in combination such that the laser is operable to produce lasing only in the fundamental mode across the operating wavelength range for frequency comb generation.

2. The laser of claim 1, wherein the waveguide has a group velocity dispersion across the operating wavelength range that is below one of: 700, 600, 500, 400, 300, 200 and 100 fs²/mm.

3. The laser of claim 1, wherein the waveguide has a total variation in group velocity dispersion across the operating wavelength range that is below one of: 300, 250, 200, 150, 100 and 50 fs²/mm.

4. The laser of claim 1, wherein the operating wavelength range for frequency comb generation is at least one of 20%, 25% and 30% of the full dynamic range.

5. The laser of claim 1,
wherein the narrow part has a positive or negative group velocity dispersion across the operating wavelength range, and
wherein the wide part has a negative or positive group velocity dispersion across the operating wavelength range of opposite sign to the group velocity dispersion of the narrow part, so that the respective group velocity dispersions of the narrow and wide parts counteract each other.

6. The laser of claim 1,
wherein the group velocity dispersion of the narrow part has a negative or positive slope as a function of wavelength, and
wherein the group velocity dispersion of the wide part has a positive or negative slope as a function of wavelength that is of opposite sign to that of the narrow part, so that the narrow and wide parts in combination result in the waveguide having a reduced variation in group velocity dispersion across the operating wavelength range compared with either the narrow or wide parts alone.

7. The laser of claim 1, wherein the wide part has a length that is greater than at least one of 50%, 60% and 70% of the length of the narrow part.

8. The laser of claim 1, wherein the wide part has a length that is greater than at least one of 50%, 60% and 70% of the optical path length between the end mirrors.

9. The laser of claim 1, wherein the waveguide is formed in a semiconductor chip by:
a waveguide core layer which itself comprises a sequence of layers to provide multiple quantum wells with respective subbands;
lower and upper waveguide cladding layers arranged either side of the waveguide core layer to provide vertical confinement of waveguiding modes; and
lateral structure to provide lateral confinement of the waveguiding modes.

10. The laser of claim 9, wherein the subbands define at least one intersubband transition operable to generate quantum cascade laser action.

11. The laser of claim 9, wherein the subbands define at least one interband transition operable to generate interband cascade laser action.

12. The laser of claim 9, wherein the semiconductor chip further comprises front and back facets that provide the end mirrors.

13. The laser of claim 1, wherein the narrow part comprises a section of a first constant width and the wide part comprises two sections of a second constant width greater than the first width, and wherein the waveguide further comprises two tapered sections of varying width, each to provide a continuous transition between the first and second constant width sections of adjacent narrow and wide sections.

14. The laser of claim 1, wherein the narrow part consists of one or more tapered sections of varying width and wherein the wide part comprises one or more length sections of a constant width matched to a maximum width end of the or each adjacent tapered section.

15. The laser of claim 1, wherein the narrow part consists of one or more tapered sections of varying width.

16. The laser of claim 1, wherein the wide part consists of one or more tapered sections of varying width.

17. The laser of claim 1, wherein the narrow part and the wide part consist of one or more tapered sections of varying width.

18. The laser of claim 1, wherein the narrow part comprises a section of a first constant width and the wide part comprises a section of a second constant width greater than the first width, and wherein the waveguide further comprises a tapered section of varying width to provide a continuous transition between the first and second constant width sections.
